(19) United States
(12) Patent Application Publication
(10) Pub. No.: US 2018/0183405 A1
(43) Pub. Date: Jun. 28, 2018

(54) BULK BAW RESONATOR HAVING ELECTRICALLY INSULATING SUBSTRATE

(71) Applicant: Avago Technologies General IP (Singapore) Pte. Ltd, Singapore (SG)

(72) Inventors: Chris Feng, Fort Collins, CO (US); Phil Nikkel, Loveland, CO (US); John Choy, Westminster, CO (US)

(21) Appl. No.: 15/390,430

(22) Filed: Dec. 23, 2016

(51) Int. Cl. H03H 9/17; H03H 9/54

(52) U.S. Cl. CPC H03H 9/17; H03H 9/54

(57) ABSTRACT

A bulk acoustic wave (BAW) resonator is disclosed. The BAW resonator includes an electrically insulating substrate, and a first electrode disposed on and in direct contact with an upper surface of the electrically insulating substrate. A second electrode is disposed over a piezoelectric layer, which is disposed over the first electrode.

### BACKGROUND

In many electronic applications, electrical resonators are used. For example, in many wireless communications devices, radio frequency (rf) and microwave frequency resonators are used as filters to improve reception and transmission of signals. Filters typically include inductors and capacitors, and more recently resonators.

As will be appreciated, it is desirable to reduce the size of components of electronic devices. Many known filter technologies present a barrier to overall system miniaturization. With the need to reduce component size, a class of resonators based on the piezoelectric effect has emerged. In piezoelectric-based resonators, acoustic resonant modes are generated in the piezoelectric material. These acoustic waves are converted into electrical waves for use in electrical applications.

One type of piezoelectric resonator is a Bulk Acoustic Wave (BAW) resonator. The BAW resonator has the advantage of small size and lends itself to Integrated Circuit (IC) manufacturing tools and techniques. The BAW includes an acoustic stack comprising, inter alia, a layer of piezoelectric material disposed between two electrodes. Acoustic waves achieve resonance across the acoustic stack, with the resonant frequency of the waves being determined by the materials in the acoustic stack.

Many BAW resonators include a substrate made of a semiconductor material, such as silicon. Electromagnetic fields generated in the acoustic stack, for example, can induce currents in the semiconductor substrates. These induced currents themselves generate electromagnetic radiation that can interfere with the desired electrical signals of the BAW resonator and can degrade the performance of devices (e.g., filters) that incorporate the BAW resonator. For example, these induced currents can contribute to intermodulation distortion (IMD), which is a measure of linearity for a wide range of radio frequency (RF) and microwave components. Fundamentally, IMD describes the ratio (in dB) between the power of fundamental tones and third-order distortion products, and it is desirable to reduce IMD products, which adversely impact desired linear behavior of devices (e.g., electrical filters) that incorporate BAW resonators.

In an effort to reduce currents induced by electromagnetic fields in the vicinity of the semiconductor substrates of BAW resonators, and thereby reduce IMD and other sources of distortion, semiconductor substrates used in BAW resonators are often made from undoped, highly resistive material. While some improvements are realized using undoped, highly resistive materials for the substrate, third order IMD products (IMD3) remain problematic especially as higher power transmission and reception, and reduced channel spacing drives the communications industry.

What is needed, therefore, is a BAW resonator that overcomes at least the known shortcomings described above.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 shows a cross-sectional view of a BAW resonator in accordance with a representative embodiment.

FIG. 2A shows a cross-sectional view of a BAW resonator in accordance with a representative embodiment.

FIG. 2B shows a cross-sectional view of a BAW resonator in accordance with a representative embodiment.

FIG. 2C shows a top view of a BAW resonator in accordance with a representative embodiment.

FIGS. 3A-3F show cross-sectional views of a process of fabricating a BAW resonator in accordance with a representative embodiment.

FIG. 4 shows a cross-sectional view of a BAW resonator in accordance with a representative embodiment.

FIG. 5 shows a simplified schematic diagram of an electrical filter in accordance with a representative embodiment.

### DETAILED DESCRIPTION

In the following detailed description, for purposes of explanation and not limitation, example embodiments disclosing specific details are set forth in order to provide a thorough understanding of the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

In accordance with a representative embodiment, a bulk acoustic wave (BAW) resonator comprises: an electrically insulating substrate; a first electrode disposed on and in direct contact with an upper surface of the electrically insulating substrate; a second electrode; and a piezoelectric layer disposed between the first and second electrodes.

A variety of devices, structures thereof, materials and methods of fabrication are contemplated for the BAW resonators of the apparatuses of the present teachings. Various details of such devices and corresponding methods of fabrication may be found, for example, in one or more of the following U.S. patent publications: U.S. Pat. No. 6,107,721, to Lakin; U.S. Pat. Nos. 5,587,620, 5,873,153, 6,507,983, 7,388,454, 7,714,684, and 8,436,516 to Ruby et al.; U.S. Pat. Nos. 7,369,013, 7,791,434, and 8,230,562 to Fazzio, et al.; U.S. Pat. Nos. 8,188,810, 7,280,007, and 9,455,681 to Feng et al.; U.S. Pat. Nos. 8,248,185, and 8,902,023 to Choy, et al.; U.S. Pat. No. 7,345,410 to Grannen, et al.; U.S. Pat. No. 6,828,713 to Bradley, et al.; U.S. Pat. Nos. 7,561,009, 7,358,831, and 9,243,316 to Larson, III et al.; U.S. Pat. No. 9,197,185 to Zou, et al., U.S. Patent Application Publication No. 20120326807 to Choy, et al.; U.S. Pat. No. 7,629,865 to Ruby; U.S. Patent Application Publication Nos. 20110180391 and 20120177816 to Larson III, et al.; U.S. Patent Application Publication No. 20140132117 to Larson III; U.S. Patent Application Publication No. 20070205850 to Jamneala et al.; U.S. Patent Application Publication No. 20110266925 to Ruby, et al.; U.S. Patent Application Publication No. 20130015747 to Ruby, et al.; U.S. Patent Application Publication No. 20130049545 to Zou, et al.; U.S. Patent Application Publication No. 20140225682 to Burak, et al.; U.S. Patent Application Publication Nos.: 20140118090 and 20140354109 to Grannen, et al.; U.S. Patent Application Publication Nos. 20140292150 and 20140175950 to Zou, et al.; U.S. Patent Application Publication No. 20150244347 to Feng, et al.; U.S. Patent Application Publication 20150311046 to Yeh, et al.; U.S. Patent Application Publication No. 20150207489 to Bi, et al.; and U.S. patent application Ser. No. 15/335,402 to Yeh, et al. filed on Oct. 26, 2016. The entire disclosure of each of the patents, patent application publications, and patent application listed above are hereby specifically incorporated by reference herein. It is emphasized that the components, materials and methods of fabrication described in these patents and patent applications are representative, and other methods of fabrication and materials within the purview of one of ordinary skill in the art are also contemplated.

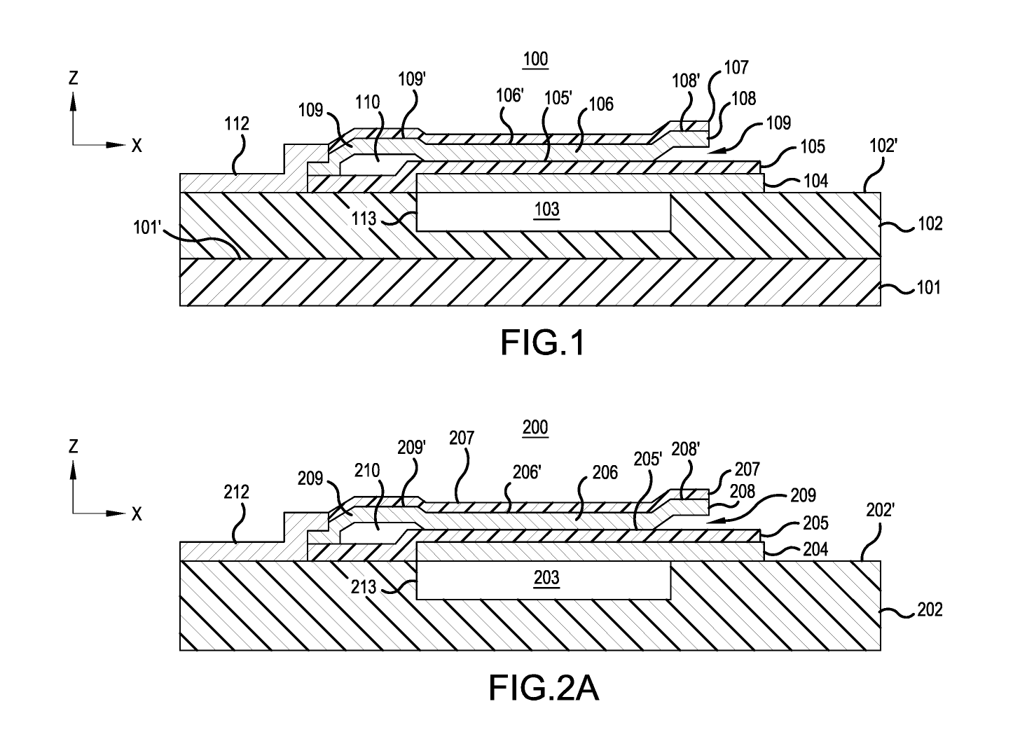

FIG. 1 is a cross-sectional view of a BAW resonator 100 in accordance with a representative embodiment. The BAW resonator 100 comprises a semiconductor substrate (sometimes referred to as a semiconductor layer) 101, an electrically insulating layer (sometimes referred to as an electrically insulating substrate) 102, and a first electrode 104 disposed over a cavity 103 provided in the electrically insulating layer 102. In accordance with a representative embodiment, the first electrode 104 is in direct contact with an upper surface 102′ of the electrically insulating layer 102.

A piezoelectric layer 105 comprises a lower surface in contact with a first electrode 104 and an upper surface 105′ in contact with a second electrode 106. As depicted in FIG. 1, the piezoelectric layer 105 extends over an edge of the first electrode 104, and is in direct contact with the upper surface 102′ of the electrically insulating layer 102.

An optional passivation layer 107 is provided over the second electrode 106. Illustratively, the passivation layer 107 can be made from various types of materials, including aluminum nitride, silicon carbide, BSG, SiO₂, SiN, polysilicon, and the like. The thickness of the passivation layer 107 should generally be sufficient to insulate the layers of BAW resonator 100 from the environment, including protection from moisture, corrosives, contaminants, and debris.

A cantilevered portion 108 of the second electrode 106 is provided on at least one side of the second electrode 106. The cantilevered portion 108 of the second electrode 106 extends over a gap 110, which illustratively comprises air. The cantilevered portion 108 may also be referred to as a ‘wing.’ An upper surface 106′ of the second electrode 106 is disposed at a first height. The cantilevered portion 108 has an upper surface 108′ disposed at a second height, which is higher than the first height. Thus, the upper surface 108′ is raised up relative to the upper surface 106′.

The BAW resonator 100 comprises a bridge 109 along the side of the BAW resonator 100 comprising an electrical interconnection 112. The bridge 109 provides a gap 110, which may be a void (e.g., air) or may be filled with a low acoustic impedance material. The bridge 109 is described more fully in U.S. Pat. No. 8,248,185, and as such many of the details of the bridge 109 are not repeated in the present application to avoid obscuring the description of the representative embodiments of the BAW resonator 100. As noted above, the cantilevered portion 108 can be disposed on more than one of the sides of the second electrode 106. However, the cantilevered portion 108 cannot be disposed on the same side of the second electrode 106 as the bridge 109.

As depicted in FIG. 1, the bridge 109 has an upper surface 109′. The upper surface 109′ is disposed substantially at a third height (z-dimension in the coordinate system depicted). The third height is higher than the first height. Thus, the upper surface 109′ is raised up relative to the upper surface 106′.

The BAW resonator 100 may also comprise one or more frame elements, which are not depicted. These frame elements, such as so-called “innies” or recesses, “outies” and “collars,” as well as other known components useful in confining energy and improving the quality factor (Q), maximizing the resistance at parallel resonance (Rₚ), and minimizing the resistance at series resonance (Rₛ), are contemplated. Many of these components are described in detail in the above-incorporated patent literature, and are not repeated to avoid obscuring the description of the present teachings.

The semiconductor substrate 101 comprises an undoped and comparatively high resistivity semiconductor material, such as undoped silicon (Si), an undoped III-V material (e.g., GaAs or InP compounds), or undoped silicon-germanium (SiGe). It is emphasized that undoped highly resistive materials for use as the substrate is merely illustrative. Specifically, because of the electrical isolation provided by the electrically insulating layer 102, the semiconductor material selected for the semiconductor substrate 101 does not have to be undoped or comparatively high resistivity semiconductor material. In fact, in other representative embodiments, the semiconductor substrate 101 can be replaced with another material, which is not a semiconductor, but has suitable electrical characteristics and mechanical strength. By way of example, a layer of suitable glass, mica, alumina non-piezoelectric aluminum nitride, or suitable ceramic materials could be used for the layer on which the electrically insulating layer 102 is disposed.

The semiconductor substrate 101 comprises an upper surface 101′ with an outer perimeter. As shown in FIG. 1, the electrically insulating layer 102 is disposed on the upper surface 101′ of the semiconductor substrate 101, and covers entirely the outer perimeter thereof. As such, the semiconductor substrate 101 comprises a substrate outer perimeter and the electrically insulating layer 102 has a layer outer perimeter, with the semiconductor substrate outer perimeter and the layer outer perimeter being aligned.

As depicted in FIG. 1, the second electrode 106 comprises an upper surface 106′. As can be seen, the upper surface 106′ is disposed substantially at a first height (z-dimension in the coordinate system depicted). Similarly, the cantilevered portion 108 comprises an upper surface 108′. The upper surface 108′ is disposed substantially at a second height (again, z-dimension in the coordinate system depicted). The second height is higher than the first height. Thus, the upper surface 106′ of the cantilevered portion is raised up relative to the upper surface 106′.

As depicted in FIG. 1, the cavity 103 has an edge 113, and the bridge 309 extends past the edge 113 of the cavity 103 (or similar reflective element, such as a mismatched Bragg reflector described below), and over the semiconductor substrate 101. As such, in a representative embodiment, the bridge 109 is disposed partially over the cavity 103, extends over the edge 113 of the cavity 103, and is disposed partially over the semiconductor substrate 101.

The combination of the first electrode 104, the piezoelectric layer 105, and the second electrode 106 is often referred to as the “acoustic stack” of the BAW resonator 100. The region of contacting overlap of the first and second electrodes 104, 106, the piezoelectric layer 105 and the cavity 103, or other reflector (e.g., Bragg reflector (see FIG. 1C)) is referred to as an active area of the BAW resonator 100. By contrast, an inactive area of the BAW resonator 100 comprises a region of overlap between first electrode 104 or second electrode 106, or both, and the piezoelectric layer 105 not disposed over the cavity 103, or other suspension structure, or acoustic mirror. As described more fully in U.S. Pat. No. 8,248,185, it is beneficial to the performance of the BAW resonator 100 to reduce the area of the inactive region of the BAW resonator 100 to the extent practical.

The electrically insulating layer 102 illustratively comprises a suitable material and is of a sufficient thickness (z-dimension of the coordinate system of FIG. 1) to effectively electrically isolate the acoustic stack from currents generated in the semiconductor substrate 101. To this end, as noted above, the environment in which the BAW resonator 100 is disposed often has a significant amount of electromagnetic fields, for example in the radio frequency (RF) and microwave spectra. These electromagnetic fields can induce currents via the carriers of the semiconductor substrate 101. In known devices, these induced currents can contribute to intermodulation distortion (IMD) products. IMD products are typically presented by the power (usually in dBm) of mixed products from two signals having different frequencies. These IMDs may be second order products (IMD2), third order products (IMD3), etc. The strength (power) of IMD products is dependent on device linearity (including the linear response of the substrate material) and two mixing signal powers. Typical non-linear materials are semiconductors, and linear materials are metal conductors (without junctions) and insulators. In accordance with certain representative embodiments, applying an electrically insulating material over a semiconductor substrate separates the non-linear semiconductor substrate and thereby reduces IMD products. In other representative embodiments described below, only an electrically insulating substrate is provided, thereby eliminating the source of IMD products (e.g., IMD3 products).

Another way to appreciate this is from the electric lump circuit for a BAW resonator (e.g., an FBAR). In accordance with a representative embodiment, the acoustic stack is separated from the nonlinear (semiconductor) substrate by a capacitor with impedance of Z, which is 1/(2*π*C*f), where C is the capacitance, and f is the frequency. Notably, C=A*εₒ*εᵣ/t, where A is area, t is thickness, and εₒ and εᵣ are absolute and relative permittivity, respectively. As can be readily appreciated, the lower the relative permittivity (εᵣ) of the electrically insulating layer 102 is, the higher Z is, and the better the electrical isolation of the acoustic stack is. Similarly, the greater the thickness of the electrically insulating layer 102, the higher Z is. In accordance with certain representative embodiments, by selecting a material having a comparatively low dielectric constant (or comparatively low relative permitivitty (εᵣ)) for the electrically insulating layer 102, and selecting a sufficient thickness, electrically insulating layer 102 acts like an electrical open between the semiconductor substrate 101 and the acoustic stack, thereby providing suitable electrical isolation of the acoustic stack from the semiconductor substrate 101, and other sources of undesired induced currents. Stated somewhat differently, the combination of the thickness of the electrically insulating layer and the relative permitivitty (εᵣ) reduces electromagnetic coupling between the semiconductor substrate and the acoustic stack of the BAW resonator 100. While not wishing to be bound to theory, Applicants surmise that a capacitance formed between the acoustic stack and the semiconductor substrate 101 is reduced by increasing the thickness (z-direction in the coordinate system of FIG. 1), or selecting a material for the electrically insulating layer 102 having a comparatively low relative permittivity (εᵣ) of the electrically insulating layer 102, or both. This reduced capacitance provides, in essence, an electrical open between the semiconductor substrate 101 and the acoustic stack. Ultimately, this improved electrical isolation is manifest in reduced power of IMDs (e.g., IMD3's), and an overall improvement in the linearity of the BAW resonator 100, and electrical components (e.g., electrical filters) that incorporate the BAW resonator 100.

Generally, the electrically insulating layer 102 has an electrical resistivity between approximately 1×10⁶ Ω-m and approximately 5×10¹⁶ Ω-m. In some representative embodiments, it is beneficial to select a material for the electrically insulating layer 102 that has a resistivity of at least 1×10¹². In other representative embodiments, it is beneficial to select a material for the electrically insulating layer 102 that has a resistivity that is greater than 10³ times that of the semiconductor substrate 101, which is, for example silicon.

Additionally, the electrically insulating layer 102 has a comparatively low relative permittivity (εᵣ), which is illustratively in the range of approximately 2.0 to approximately 10.0. Notably, for optimization in some representative embodiments, it may be useful to select a material for electrically insulating layer 102 that is in the low end of the noted range of permittivity to provide suitable capacitive decoupling from the semiconductor substrate 101. In some representative embodiments, it is beneficial to select a material for the electrically insulating layer 102 having a relative permittivity (εᵣ) that is two (2) to three (3) times less than that of the semiconductor substrate 101, which is, for example silicon. Notably, certain low-k materials, which are generally not mechanically rigid, are viable options since they are made relatively thick, and are disposed over the semiconductor substrate 101 (or other substrate with suitable mechanical strength) and under the components of the BAW resonator 100 disposed thereover.

By way of example, the electrically insulating layer 102 may comprise one or more layers of silicon dioxide (SiO₂), engineered silicon carbide (having a resistivity of at least 10⁶ Ω-m), silicon nitride (Si₃N₄), benzocylcobutene (BCB), polyimide, sapphire, or non-piezoelectric (‘glassy’) aluminum nitride (AlN), which also provides comparatively good heat dissipation. Specifically, and as described more fully below, the electrically insulating layer 102 may comprise a plurality of layers, which may be comprised of the same or different materials.

The thickness of the electrically insulating layer 102 depends on the electrical resistivity of the material selected. Generally, selection of any of the illustrative materials above requires a thickness (z-dimension) on the order of 10¹ μm. Notably, magnitude of IMD3 products decreases with increasing thickness of the electrically insulating layer 102 until a relative minimum IMD3 product magnitude is reached, at which point further increase of the thickness of the insulating layer provides no further improvement of IMD3 products. Just by way of example, a layer of SiO₂, when used for the electrically insulating layer 102 has a thickness in the range of approximately 1 μm to approximately 100 μm, or more. Again, the thickness selected for the electrically insulating layer 102 depends on its dielectric properties, and thus its ability to electrically isolate the acoustic stack from currents generated in the semiconductor substrate 101. As such, materials having an electrical resistivity greater than SiO₂ and a dielectric constant less than SiO₂, may not need as great a thickness as SiO₂, whereas materials having an electrical resistivity less than SiO₂ and a dielectric constant greater than SiO₂ would have a greater thickness.

The piezoelectric layer 105 generally comprises a highly textured piezoelectric material, such as aluminum nitride (AlN), and may be fabricated according to the teachings of patent literature incorporated above. In certain representative embodiments, the piezoelectric layer 105 may be doped with rare-earth elements to improve the acoustic coupling coefficient (kt²) of the piezoelectric layer. The rare earth elements include yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu), as known by one of ordinary skill in the art. The various embodiments contemplate incorporation of any one or more rare earth elements, although specific examples are discussed herein.

In representative embodiments in which the doped piezoelectric material is AlXN (where X is the rare-earth element), the doping elements replace only Al atoms in the AlN crystal. Accordingly, the percentage of nitrogen atoms in the piezoelectric material remains substantially the same regardless of the amount of doping. Notably, when the percentages of doping elements (e.g., Sc) in a doped AN layer are discussed herein, it is in reference to the total atoms (including nitrogen) of the AN piezoelectric layer. So, for example, and as described for example in U.S. Patent Application Publication No. 20140132117, if the Sc in the piezoelectric layer of a representative embodiment has an atomic percentage of approximately 5.0%, and the Al has an atomic percentage of approximately 95.0%, then the atomic consistency of the piezoelectric layer may then be represented as Al_{0.95}Sc_{0.05} N.

In certain representative embodiments, the piezoelectric layer 105 comprises aluminum nitride (AlN) that is doped with scandium (Sc). The atomic percentage of scandium in an aluminum nitride layer is approximately greater than 9.0% to approximately 44.0%; and in other representative embodiments, the percentage of scandium in an aluminum nitride layer is approximately greater than 5.0% to approximately 44.0%.

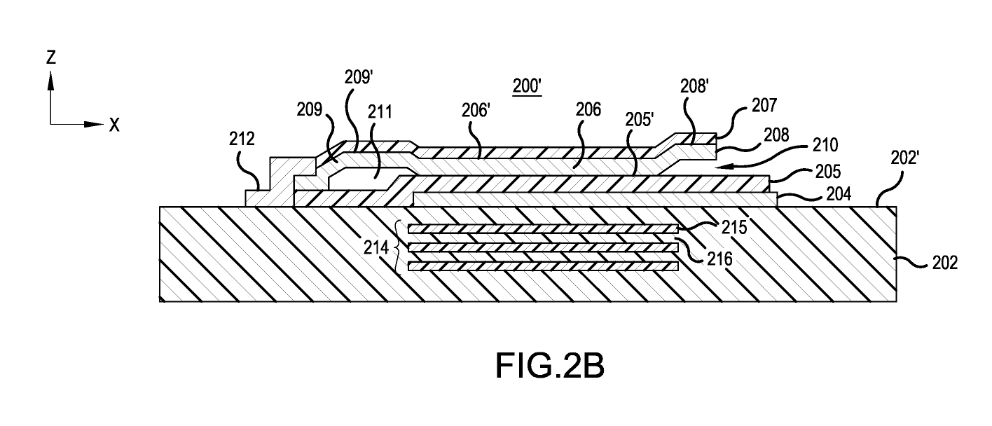

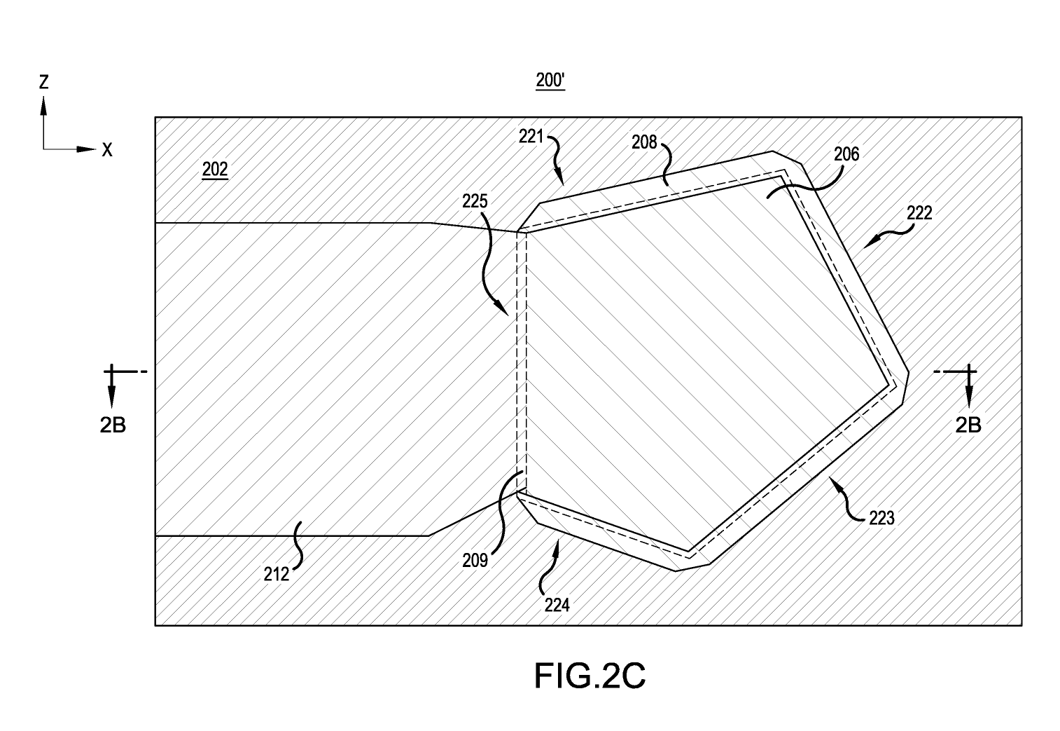

The first and second electrodes 104, 106 and the electrical interconnection 112 are made of materials that survive the fabrication sequences described below in connection with FIGS. 2A-2F. As will become clearer as the present description continues, in certain representative embodiments, the first and second electrodes 104, 106 may not comprise tungsten (W) or molybdenum (Mo), or a combination (e.g., ally or stack) of Mo and W. Rather, first and second electrodes 104, 106 are made from one or more of ruthenium, platinum, iridium, aluminum, chromium, or other suitable materials that can survive the processing materials used to fabricate the BAW resonator 100.

FIG. 2A is a cross-sectional view a BAW resonator 200 in accordance with a representative embodiment. Many aspects and details (e.g., materials, material characteristics and dimensions) of BAW resonator 200 are common to certain aspects and details of BAW resonator 100 described in connection with FIG. 1. These common aspects and details may not be repeated to avoid obscuring the presently described representative embodiments.

The BAW resonator 200 comprises an electrically insulating substrate 202, and a first electrode 204 disposed over a cavity 203 provided in the electrically insulating substrate 202. In accordance with a representative embodiment, the first electrode 204 is in direct contact with an upper surface 202′ of the electrically insulating substrate 202. Significantly, unlike BAW resonator 100, BAW resonator 200 does not comprise a semiconductor substrate, or semiconductor layer beneath the electrically insulating substrate 202.

A piezoelectric layer 205 is disposed over the first electrode 204 and comprises a lower surface in contact with the first electrode 204 and an upper surface 205′ in contact with a second electrode 206. As depicted in FIG. 2A, the piezoelectric layer 205 extends over an edge of the first electrode 204, and is in direct contact with the upper surface 202′ of the electrically insulating substrate 202.

An optional passivation layer 207 is provided over the second electrode 206. Illustratively, the passivation layer 207 can be made from various types of materials, including aluminum nitride, silicon carbide, BSG, SiO₂, SiN, polysilicon, and the like. The thickness of the passivation layer 207 should generally be sufficient to insulate the layers of BAW resonator 200 from the environment, including protection from moisture, corrosives, contaminants, and debris.

A cantilevered portion 208 of the second electrode 206 is provided on at least one side of the second electrode 206, and has an upper surface 208′. The cantilevered portion 208 of the second electrode 206 extends over a gap 210, which illustratively comprises air. The cantilevered portion 208 may also be referred to as a ‘wing.’

The BAW resonator 200 may also comprise one or more frame elements, which are not depicted. These frame elements, such as so-called “innies” or recesses, “outies” and “collars,” as well as other known components useful in confining energy and improving the quality factor (Q), maximizing the resistance at parallel resonance (Rₚ), and minimizing the resistance at series resonance (Rₛ), are contemplated. Many of these components are described in detail in the above-incorporated patent literature, and are not repeated to avoid obscuring the description of the present teachings.

As depicted in FIG. 2A, the second electrode 206 comprises an upper surface 206′. As can be seen, the upper surface 206′ is disposed substantially at a first height (z-dimension in the coordinate system depicted). Similarly, a cantilevered portion 208 comprises an upper surface 208′. The upper surface 208′ is disposed substantially at a second height (again, z-dimension in the coordinate system depicted). The second height is higher than the first height. Thus, the upper surface 206′ of the cantilevered portion 208 is raised up relative to the upper surface 206′.

As also depicted in FIG. 2A, the bridge 209 has upper surface 209′. The upper surface 209′ is disposed substantially at a third height (again, z-dimension in the coordinate system depicted). The third height is higher than the first height. Thus, the upper surface 209′ is raised up relative to the upper surface 206′.

The BAW resonator 200 comprises a bridge 209 along the side that comprises an interconnection 212. The bridge 209 provides a gap 210, which may be a void (e.g., air) or may be filled with a low acoustic impedance material. The bridge 209 is described more fully in U.S. Pat. No. 8,248,185, and as such many of the details of the bridge 209 are not repeated in the present application to avoid obscuring the description of the representative embodiments of the BAW resonator 200. As noted above, the cantilevered portion 208 can be disposed on more than one of the sides of the second electrode 206. However, the cantilevered portion 208 cannot be disposed on the same side of the second electrode 206 as the bridge 209.

As depicted in FIG. 2A, the cavity 203 has edge 213, and the bridge 209 extends past the edge 213 of the cavity 203 (or similar reflective element, such as a mismatched Bragg reflector described below), and over the electrically insulating substrate 202. As such, in a representative embodiment, the bridge 209 is disposed partially over the cavity 203, extends over the edge 213 of the cavity 203, and is disposed partially over the electrically insulating substrate 202.

The combination of the first electrode 204, the piezoelectric layer 205, and the second electrode 206 is often referred to as the “acoustic stack” of the BAW resonator 200. The region of contacting overlap of the first and second electrodes 204, 206, the piezoelectric layer 205 and the cavity 203, or other reflector (e.g., Bragg reflector (see FIG. 2B)) is referred to as an active area of the BAW resonator 200. By contrast, an inactive area of the BAW resonator 200 comprises a region of overlap between first electrode 204 or second electrode 206, or both, and the piezoelectric layer 205 not disposed over the cavity 203, or other suspension structure, or acoustic mirror. As described more fully in U.S. Pat. No. 8,248,185, it is beneficial to the performance of the BAW resonator 200 to reduce the area of the inactive region of the BAW resonator 200 to the extent practical.

The electrically insulating substrate 202 illustratively comprises a suitable material of a sufficient thickness (z-dimension of the coordinate system of FIG. 2A) to effectively electrically isolate the acoustic stack. As can be appreciated, by eliminating the semiconductor substrate (e.g., semiconductor substrate 101 of the representative embodiments of FIG. 1), this source of induced currents that can contribute to IMDs (e.g., IMDIII's) is eliminated. Moreover, because the electrically insulating substrate 202 has such a low carrier concentration, no currents are induced therein. As such, electromagnetic radiation prevalent in the environment of BAW resonator 200 cannot induce current in the electrically insulating substrate 202, thereby avoiding a significant source of IMDs in known BAW resonators and electrical components comprising BAW resonators. Stated somewhat differently, as described above, the electrically insulating layer 102 of the representative embodiments of FIG. 1 provides electrical isolation from the semiconductor substrate 101. By contrast, by providing the electrically insulating substrate 202 of the representative embodiments of FIG. 2A, one source of IMDs is eliminated.

Generally, the electrically insulating substrate 202 has an electrical resistivity between approximately 1×10⁶ Ω-m and approximately 5×10¹⁶ Ω-m. In some representative embodiments, it is beneficial to select a material for the electrically insulating layer 102 that has a resistivity of at least 1×10¹². By way of example, the electrically insulating substrate 202 may comprise one or more layers of silicon dioxide (SiO₂), silicon nitride (Si₃N₄), engineered silicon carbide (having a resistivity of at least 10⁶ Ω-m), benzocylcobutene (BCB), polyimide, sapphire, or non-piezoelectric (‘glassy’) aluminum nitride (AlN), which also provides comparatively good heat dissipation. Specifically, and as described more fully below, the electrically insulating substrate 202 may comprise a plurality of layers, which may be of the same or different materials.

Additionally, the electrically insulating layer 202 has a comparatively low relative permittivity (εᵣ), which is illustratively in the range of approximately 2.0 to approximately 10.0. Notably, for optimization in some representative embodiments, it may be useful to select a material for electrically insulating layer 202 that is in the low end of the noted range of permittivity.

Unlike electrically insulating layer 102, because there is no semiconductor substrate beneath the electrically insulating substrate 202 that must be electrically isolated from the acoustic stack, the thickness of the electrically insulating substrate 202 is not necessarily selected to ensure this electrical isolation, but rather to provide sufficient mechanical strength for wafer handling during wafer processing. Generally, selection of any of the illustrative materials above requires a thickness (z-dimension) on the order of 10¹ μm. Just by way of example, a layer of SiO₂, when used for the electrically insulating substrate 202 has a thickness in the range of approximately 1 μm to approximately 100 μm, or more.

The piezoelectric layer 205 generally comprises a highly textured piezoelectric material, such as aluminum nitride (AlN), and may be fabricated according to the teachings of patent literature incorporated above. In certain representative embodiments, the piezoelectric layer 205 may be doped with rare-earth elements to improve the acoustic coupling coefficient (kt²). The rare earth elements include yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu), as known by one of ordinary skill in the art. The various embodiments contemplate incorporation of any one or more rare earth elements, although specific examples are discussed herein.

In representative embodiments in which the doped piezoelectric material is AlXN (where X is the rare-earth element), the doping elements replace only Al atoms in the AlN crystal. Accordingly, the percentage of nitrogen atoms in the piezoelectric material remains substantially the same regardless of the amount of doping. Notably, when the percentages of doping elements (e.g., Sc) in a doped AN layer are discussed herein, it is in reference to the total atoms (including nitrogen) of the AN piezoelectric layer. So, for example, and as described for example in U.S. Patent Application Publication No. 20140132117, if the Sc in the piezoelectric layer of a representative embodiment has an atomic percentage of approximately 5.0%, and the Al has an atomic percentage of approximately 95.0%, then the atomic consistency of the piezoelectric layer may then be represented as Al_{0.95}Sc_{0.05} N.

In certain representative embodiments, the piezoelectric layer 205 comprises aluminum nitride (AlN) that is doped with scandium (Sc). The atomic percentage of scandium in an aluminum nitride layer is approximately greater than 9.0% to approximately 44.0%; and in other representative embodiments, the percentage of scandium in an aluminum nitride layer is approximately greater than 5.0% to approximately 44.0%.

The first and second electrodes 204, 206 and the interconnection 212 are made of materials that can survive the fabrication sequences described below in connection with FIGS. 2A-2F. As will become clearer as the present description continues, in certain representative embodiments, the first and second electrodes 204, 206 may not comprise tungsten (W) or molybdenum. Rather, first and second electrodes 204, 206 are made from one or more of ruthenium, platinum, iridium, aluminum, chromium, or other suitable materials that can survive the processing materials used to fabricate the BAW resonator 200.

FIG. 2B is a cross-sectional view a BAW resonator 200′ in accordance with a representative embodiment. Many aspects and details (e.g., materials, material characteristics and dimensions) of BAW resonator 200′ are common to certain aspects and details of BAW resonator 100 and BAW resonator 200 described in connection with FIGS. 1 and 2A. These common aspects and details may not be repeated to avoid obscuring the presently described representative embodiments.

Notably, the BAW resonator 200′ is substantively identical to BAW resonator 200, with the exception of the acoustic reflector disposed in the electrically insulating substrate. To this end, rather than cavity 203, the BAW resonator 200′ comprises an acoustic Bragg reflector 214 comprising alternating low acoustic impedance layers 216 and high acoustic impedance layers 215. Preferably, the low acoustic impedance layers 216 and high acoustic impedance layers 215 are selected to provide a comparatively high ratio of acoustic impedance. By way of illustration, the low acoustic impedance layers 216 comprise a dielectric material such as silicon dioxide (e.g., the same material as the electrically insulating substrate 202). While the high acoustic impedance layers 215 may be tungsten or iridium, it is preferable that the high acoustic impedance layers 216 comprise a high acoustic impedance dielectric material, so there is no electrical coupling between the acoustic stack of BAW resonator 200′ and high acoustic impedance layers 215 underneath. The process for fabricating the acoustic Bragg reflector 214 is described below.

FIG. 2C shows a top view of BAW resonator 200′ taken along 2B-2B. Notably, the passivation layer 207 is not shown in FIG. 2C so details are not obscured.

The BAW resonator 200′ comprises second electrode 206, comprising cantilevered portions 208 along first through fourth sides 221, 222, 223 and 224. The interconnection 212 is connected to a fifth side 225, which is also the side where the bridge 209 is located. Notably, the cantilevered portions 208 can be disposed on at least one of the first˜fourth sides 221-224, but not along the fifth side 225, where the interconnection 212 makes an electrical connection with the BAW resonator 200′.

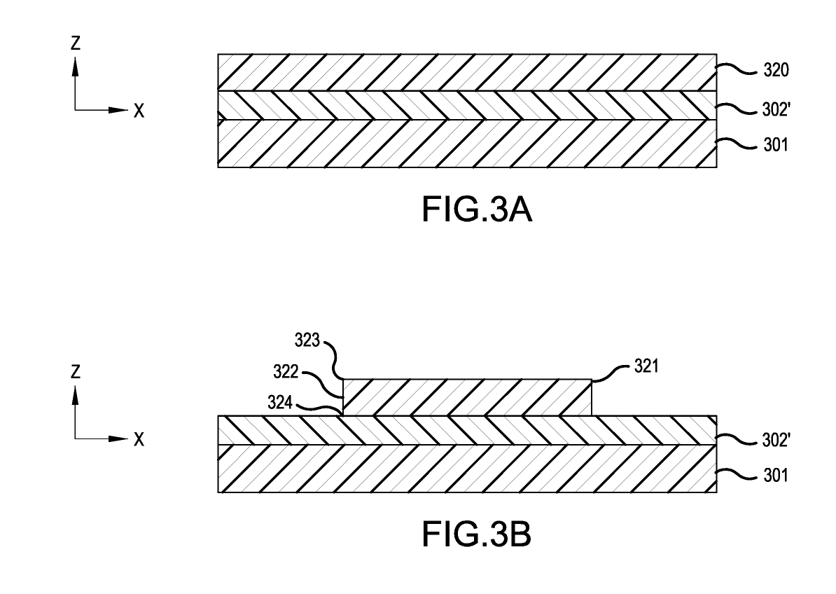

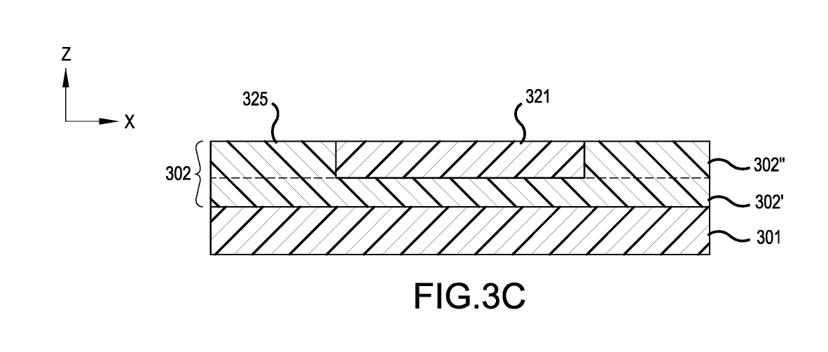

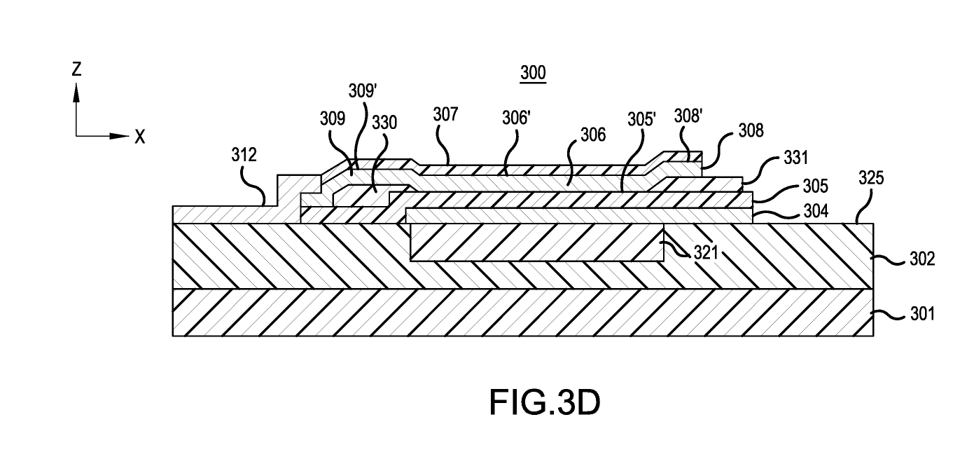

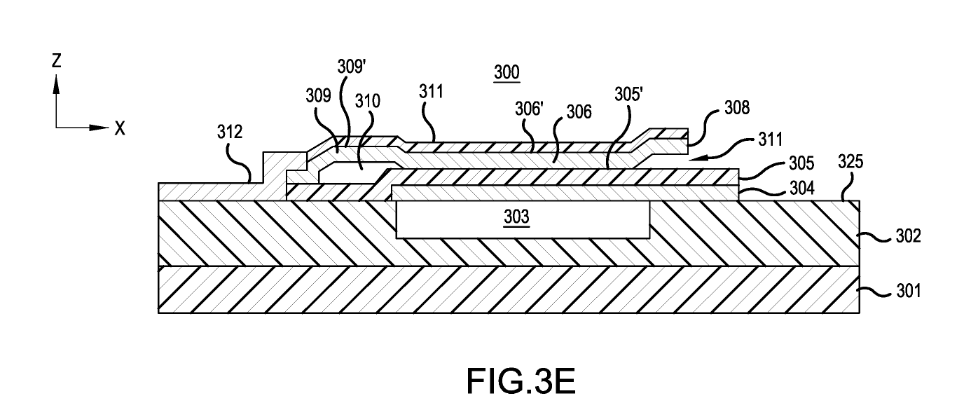

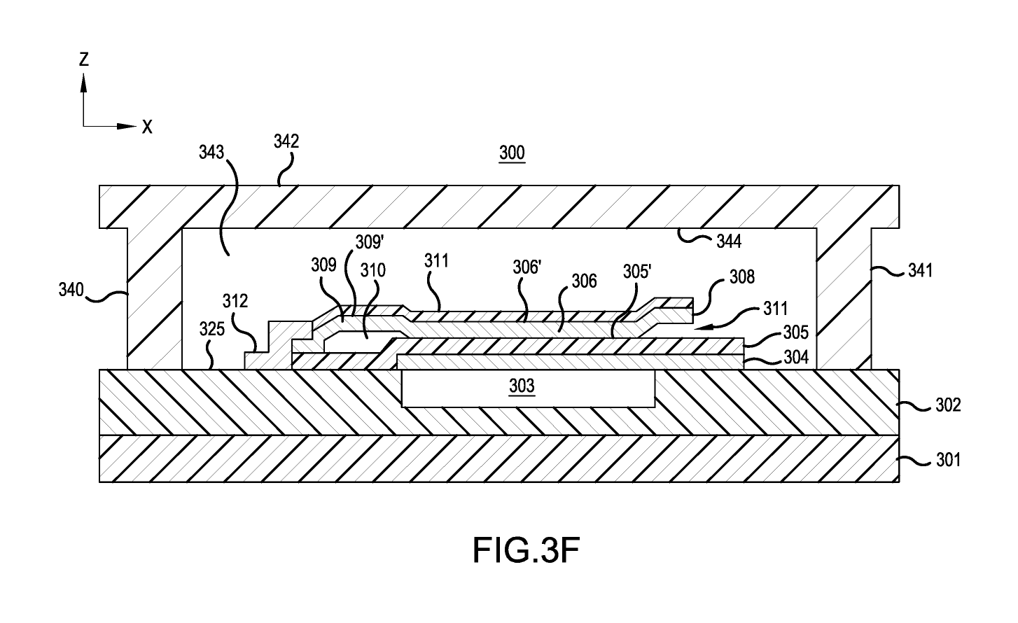

FIGS. 3A-3F show cross-sectional views of a process of fabricating a BAW resonator 300 in accordance with a representative embodiment. Many aspects and details (e.g., materials, material characteristics and dimensions) of BAW resonator 300 are common to certain aspects and details of BAW resonators 100, 200, and 200′ described in connection with FIGS. 1-2B. These common aspects and details may not be repeated to avoid obscuring the presently described representative embodiments.

Turning to FIG. 3A, an electrically insulating layer 302′ is disposed between a semiconductor substrate 301 and a sacrificial layer 320. As will be appreciated as the present description continues, the fabrication sequence of FIGS. 3A-3F results in a BAW resonator substantively identical to BAW resonator 100, and thus includes the semiconductor substrate 301. However, the fabrication sequence of FIGS. 3A-3F may be slightly modified to realize a BAW resonator comprising an electrically insulating substrate (e.g., electrically insulating substrate 202), and no semiconductor substrate. Essentially, the step of providing the semiconductor substrate 301 is foregone, and providing the electrically insulating layer 302′ begins the fabrication sequence.

The semiconductor substrate 301 is illustratively an undoped and comparatively high resistivity semiconductor material, such as undoped silicon (Si), an undoped III-V material (e.g., GaAs or InP compounds), or undoped silicon-germanium (SiGe). As will be appreciated, the relatively low carrier concentration in the selected semiconductor substrate 301 reduces the magnitude of currents induced therein, and eases the electrical insulation and isolation requirements of the electrically insulating layer 302′.

However, because of the electrical isolation provided by the electrically insulating layer 302′, the semiconductor material selected for the semiconductor substrate 301 does not have to be undoped or comparatively high resistivity semiconductor material. In fact, in other representative embodiments, the semiconductor substrate 301 can be replaced with another material, which is not a semiconductor, but has suitable electrical characteristics and mechanical strength. By way of example, as noted above, a layer of suitable glass, ceramic, or polymer, could be used for the layer on which the electrically insulating layer 302′ is disposed.

As noted above, IMD3 product magnitude decreases with increasing thickness of the electrically insulating layer 302′ until a relative minimum IMD3 product magnitude is reached, at which point further increase of the thickness of the insulating layer provides no further improvement of IMD3 products. Just by way of example, a layer of SiO₂, when used for the electrically insulating layer 302′ has a thickness in the range of approximately 1 μm to approximately 100 μm, or more. Again, the thickness selected for the electrically insulating layer 302′ depends on its dielectric properties, and thus its ability to electrically isolate the acoustic stack from currents generated in the semiconductor substrate 301. As such, materials having an electrical resistivity greater than SiO₂ and a dielectric constant less than SiO₂ may not need as great a thickness as SiO₂, whereas materials having an electrical resistivity less than SiO₂ and dielectric constant greater than SiO₂ would have a greater thickness.

The electrically insulating layer 302′ illustratively has an electrical resistivity between approximately 1×10⁶ Ω-m and approximately 5×10¹⁶ Ω-m. In some representative embodiments, it is beneficial to select a material for the electrically insulating layer 302′ that has a resistivity of at least 1×10¹². In other representative embodiments, it is beneficial to select a material for the electrically insulating layer 302′ that has a resistivity that is greater than 10³ times that of the semiconductor substrate 301, which is, for example silicon.

Additionally, the electrically insulating layer 302′ has a comparatively relative permittivity (εᵣ), which is illustratively in the range of approximately 2.0 to approximately 10.0. Notably, for optimization in some representative embodiments, it may be useful to select a material for electrically insulating layer 302′ that is in the low end of the noted range of permittivity to shield the semiconductor substrate 301. In some representative embodiments, it is beneficial to select a material for the electrically insulating layer 302′ having a relative permittivity (εᵣ) that is two (2) to three (3) times less than that of the semiconductor substrate 101, which is, for example silicon. Notably, certain low-k materials, which are generally not mechanically rigid, are viable options since they are made relatively thick, and are disposed over the semiconductor substrate 301 (or other substrate with suitable mechanical strength) and under the components of the BAW resonator 100 disposed thereover.

By way of example, the electrically insulating layer 302′ may comprise one or more layers of silicon dioxide (SiO₂), silicon nitride (Si₃N₄), engineered silicon carbide (having a resistivity of at least 10⁶ Ω-m), benzocylcobutene (BCB), polyimide, or non-piezoelectric (‘glassy’) aluminum nitride (AlN), which also provides comparatively good heat dissipation. Specifically, and as described more fully in connection with FIG. 3C, the electrically insulating layer 302′ may comprise a plurality of layers, which may be of the same or different materials.

The electrically insulating layer 302′ is deposited on the semiconductor substrate 301 using a known method commensurate with the selected material. Such methods include, but are not limited to, chemical vapor deposition (CVD) or plasma enhanced CVD (PECVD), or physical vapor deposition (PVD). By way of example, in a representative embodiment, the electrically insulating layer 302′ is SiO₂ fabricated by PECVD using tetraethoxysilane (TEOS).

The sacrificial layer 320 is selected to be removed using a process that does not detrimentally remove other materials of the resultant BAW resonator, for example the electrically insulating layer 302′. In accordance with a representative embodiment, illustrative candidates for the sacrificial layer 320 include, but are not limited to amorphous or polycrystalline silicon, molybdenum (Mo), tungsten (W), germanium (Ge), SiGe, and titanium tungsten (TiW).

The sacrificial layer 320 is also deposited using a known method commensurate with the material selected for the sacrificial layer 320. For example, if the sacrificial layer 320 comprises silicon, the sacrificial layer 320 can be deposited using a known physical vapor deposition (PVD), chemical vapor deposition (CVD), or plasma enhanced chemical vapor deposition (PECVD) method. As will be appreciated, the sacrificial layer 320 is deposited at a thickness (z-direction of the coordinate system of FIG. 3A) great enough to provide adequate depth of the cavity 303 from which it is formed. By way of example, the sacrificial layer 320 is deposited to a thickness in the range of approximately 500 A to approximately 10 μm. After fabrication of the sacrificial layer 320, a known masking and etching step is used to form a sacrificial island 321 depicted in FIG. 3B. By way of illustration, a suitable mask can be provided over the sacrificial layer 320, and a plasma etching process can be carried out. Such a dry etching method may be a deep reactive ion etching (DRIE) process, such as the known Bosch Method, which provides comparatively deep etches and comparatively high aspect-ratio etches. Alternatively, a wet etch (e.g., HF-nitric solution, or potassium hydroxide (KOH)) can be carried out to realize the sacrificial island 321.

Notably, the sacrificial island 321 has comparatively vertical sides 322, and sharp corners 323, 324. This is not essential, and, based on the etching method, the width (x-direction of the coordinate system of FIG. 3B) may decrease between the corners 323, 324, resulting in sides 322 being oriented at an angle. As will be appreciated as the present description continues, the dimensions and shape of the sacrificial island 321 dictate the shape of the resultant cavity.

Turning to FIG. 3C, another electrically insulating layer 302″ is formed over the electrically insulating layer 302′ to provide the electrically insulating substrate 302. In accordance with a representative embodiment, the electrically insulating layers 302′, 302″ are made of the same material and using the same methods. So, for example, the electrically insulating layers 302′, 302″ comprise SiO₂ fabricated using a TEOS precursor. Alternatively, the electrically insulating layers 302′, 302″ are fabricated from different materials. For example, electrically insulating layer 302′ may comprise SiO₂, and the electrically insulating layer 302″ may be Si₃N₄. Providing different materials for the electrically insulating layers 302′, 302″ may improve the ability to planarize the upper surface of the electrically insulating substrate 302. Notably, the electrically insulating layer 302″ may comprise a plurality of layers of the same or of different materials.

Like electrically insulating layer 302′, electrically insulating layer 302″ illustratively has an electrical resistivity between approximately 1×10⁶ Ω-m and approximately 5×10¹⁶ Ω-m. In some representative embodiments, it is beneficial to select a material for the electrically insulating layer 302″ that has a resistivity of at least 1×10¹². In other representative embodiments, it is beneficial to select a material for the electrically insulating layer 302″ that has a resistivity that is greater than 10³ times that of the semiconductor substrate 301, which is, for example silicon. Additionally, the electrically insulating layer 302″ has a comparatively relative permittivity (εᵣ), which is illustratively in the range of approximately 2.0 to approximately 10.0. Notably, for optimization in some representative embodiments, it may be useful to select a material for electrically insulating layer 302″ that is in the low end of the noted range of permittivity to provide capacitive decoupling from the semiconductor substrate 301. In some representative embodiments, it is beneficial to select a material for the electrically insulating layer 302′ having a relative permittivity (εᵣ) that is two (2) to three (3) times less than that of the semiconductor substrate 101, which is, for example silicon.

By way of example, the electrically insulating layer 302″ may comprise one or more layers of silicon dioxide (SiO₂), engineered silicon carbide (having a resistivity of at least 10⁶ Ω-m), silicon nitride (Si₃N₄), benzocylcobutene (BCB), polyimide, sapphire, or non-piezoelectric (‘glassy’) aluminum nitride (AlN), which also provides comparatively good heat dissipation.

After fabrication of the electrically insulating layer 302″, an upper surface 325 is chemically-mechanically polished to provide a suitable surface over which to form the acoustic stack and other elements of a BAW resonator.

Turning to FIG. 3D, the next steps of fabrication are depicted. A first electrode 304 is deposited using a known method directly on the upper surface 325 and thereby directly on an upper surface 325 of the electrically insulating layer 302″, and directly on an upper surface 325 of the sacrificial island 321. In the presently described representative embodiment, the first electrode 304 comprises a material that will not be substantially eroded or substantially damaged when sacrificial material is removed. As such, in the presently described embodiment, the first electrode 304 does not comprise tungsten or molybdenum.

Next, a piezoelectric layer 305 is deposited over the first electrode 304. The piezoelectric layer 305 is illustratively AlN, and may be doped with a rare-earth element (e.g., Sc) as described above. The piezoelectric layer 305 comprises a lower surface in contact with the first electrode 304.

After formation of the piezoelectric layer 305, a photoresist (not shown) is patterned, and a first sacrificial layer 330 and a second sacrificial layer 331 are deposited for eventual formation of a bridge 309 and a cantilevered portion 308. The first and second sacrificial layers 330, 331 comprise the same material as the sacrificial island 321. Notably, the first and second sacrificial layers 330, 331 are formed from the same film deposition or “layer”, and are formed to provide the desired shape and dimensions of the bridge 309 and the cantilevered portion 308. As such, known etching methods such as plasma etching or wet etching may be used to form the tapered sides as desired.

Next, a second electrode 306 is deposited over the underlying structure, and a passivation layer 307 is optionally provided over the second electrode 306.

In accordance with a representative embodiment, in which silicon is used for the sacrificial island 321, the first sacrificial layer 330 and the second sacrificial layer 331 are removed using a gaseous or “dry” etch sequence using xenon difluoride (XeF₂) to remove the sacrificial material. Notably, other materials selected to have a comparatively high etch rate in XeF₂ may be used for the sacrificial island 321, the first sacrificial layer 330, and the second sacrificial layer 331.

Notably, before the etching sequence is undertaken, a comparatively thin (e.g., 50 A to 300 A) layer (not shown) of AlN, silicon carbide (SiC), or suitable polymer may be deposited using a known method over the second electrode 306, frame elements (not shown), etc. This etch stop layer is beneficial to protect elements (e.g., frame elements) made of molybdenum, tungsten and other materials desired to survive the etch release step using XeF₂.

In accordance with a representative embodiment, the underside of the semiconductor substrate 301 sits on a wafer chuck, and a metallic ring wafer clamp is applied around the perimeter of the wafer, allowing little XeF₂ to reach the side walls of the semiconductor substrate 301. As such, the XeF₂ is introduced into a reaction chamber designed to allow the XeF₂ to react primarily with the sacrificial material, while preventing or limiting exposure of other silicon elements desired to survive the etch release from being significantly impacted.

In a representative embodiment, the primary reaction occurring between XeF2 and silicon is:

2XeF₂+Si↔2Xe(g)+SiF₄(g)

The sequence of reaction comprises a non-dissociative adsorption of XeF2 at the surface of the (silicon) sacrificial island 321, first sacrificial layer 330, and second sacrificial layer 331. Next, dissociation of the absorbed gas, F₂ occurs, followed by a reaction between the adsorbed atoms and the silicon surface, thereby forming an adsorbed product molecule, SiF4 (ads). Next, desorption of the product molecule (SiF₄) into the gas phase occurs, followed by volatilization of non-reactive residue (dissociated Xe) from the etched surface. In addition, it is beneficial to use a photoresist protection mask to protect the edge of the second electrode 306 during the XeF₂ release etch. This is removed following release by O₂ ashing. This processing sequence, which is often referred to as a patterned release, includes opening photo resist only at desired areas where the sacrificial layer is exposed so that it reacts with XeF2. After the release etch step is complete, a resist strip using O₂ ashing is carried out. Among other benefits, O₂ ashing is preferred over a wet resist strip, which could damage the released membranes.

Turning to FIG. 3E, after the release of the sacrificial island 321, the first sacrificial layer 330 and the second sacrificial layer 331, a cavity 303, a cantilevered portion 308 with gap 310, and a bridge 309 with a gap 310 are revealed.

Turning to FIG. 3F, BAW resonator 300 according to a representative embodiment is depicted. The BAW resonator 300 comprises a first polymer post 340, a second polymer post 341, and a polymer lid 342 disposed over the first and second polymer posts 340, 341. The first polymer post 340, the second polymer post 341, and the polymer lid 342 provide a void 343 between an inner surface 344 of the polymer lid 342, and an opposing upper surface 325 of the electrically insulating layer 302. This type of structure, sometimes referred to as a microcap, provides a substantially hermetically sealed void. Beneficially, the polymer microcap structures (first and second posts, and lid) are applied to complete on-wafer capping before singulation and final product construction. Further details of such polymer microcap structures may be found in U.S. Pat. Nos. 8,102,044, 6,979,597, 6,787,897, 6,777,263, 6,429,511, 6,376,280, 6,265,246; and U.S. Patent Application Publication No. 2010096745 to Ruby, et al., the entire disclosures of which are specifically incorporated herein by reference.

Among other benefits, the polymer microcap further reduces the susceptibility of BAW resonator 300 to IMDs. To this end, in many known microcap structures, the posts and the lids are made of the same semiconductor material as the substrate. These structures, which include carriers, are susceptible to induced currents from electromagnetic radiation in their vicinity. By contrast, the first polymer post 340, the second polymer post 341, and the polymer lid 342 are made of a substantially electrically insulating material, which, like the electrically insulating layer 302, is not susceptible to such induced currents to an appreciable degree.

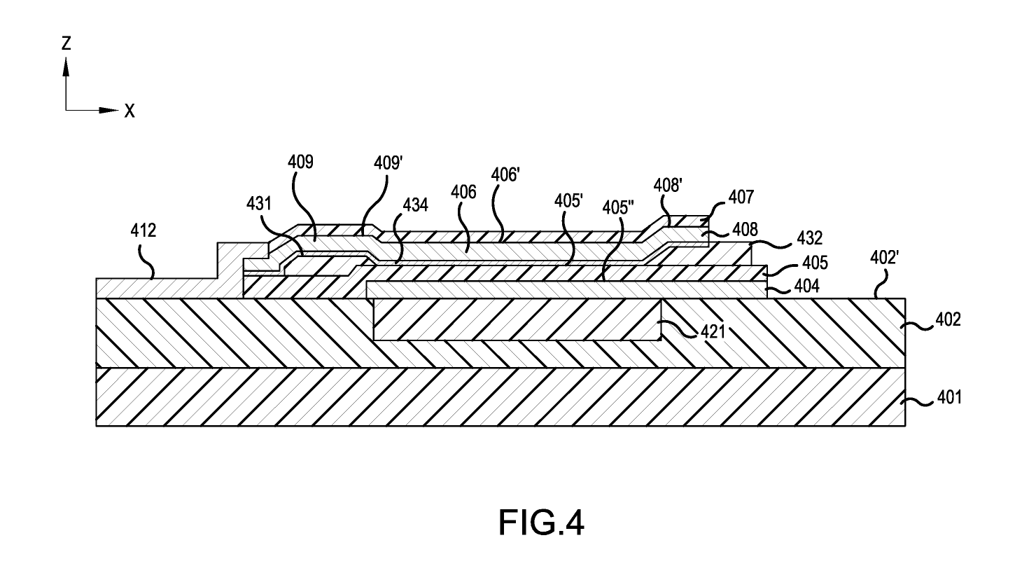

FIG. 4 is a cross-sectional view of a BAW resonator 400 in accordance with a representative embodiment. Many aspects and details (e.g., materials, material characteristics and dimensions) of BAW resonator 400 are common to certain aspects and details of BAW resonators 100, 200, 200′ and, 300 described in connection with FIGS. 1-3F. These common aspects and details may not be repeated to avoid obscuring the presently described representative embodiments.

The BAW resonator 400 comprises a semiconductor substrate (sometimes referred to as a layer) 401, an electrically insulating layer 402, and a first electrode 404 in direct contact with an upper surface 402′ of the electrically insulating layer 402.

Generally, the electrically insulating layer 402 has an electrical resistivity between approximately 1×10⁶ Ω-m and approximately 5×10¹⁶ Ω-m. In some representative embodiments, it is beneficial to select a material for the electrically insulating layer 402 that has a resistivity of at least 1×10¹². In other representative embodiments it is it is beneficial to select a material for the electrically insulating layer 402 that has a resistivity that is greater than 10³ times that of the semiconductor substrate 401, which is, for example silicon.

Additionally, the electrically insulating layer 402 has a comparatively low relative permittivity (εᵣ), which is illustratively in the range of approximately 2.0 to approximately 10.0. Notably, for optimization in some representative embodiments, it may be useful to select a material for electrically insulating layer 402 that is in the low end of the noted range of permittivity to provide capacitive decoupling from the semiconductor substrate 401. In some representative embodiments, it is beneficial to select a material for the electrically insulating layer 402 having a relative permittivity (εᵣ) that is two (2) to three (3) times less than that of the semiconductor substrate 401, which is, for example silicon. Notably, certain low-k materials, which are generally not mechanically rigid, are viable options since they are made relatively thick, and are disposed over the semiconductor substrate 401 (or other substrate with suitable mechanical strength) and under the components of the BAW resonator 400 disposed thereover.

By way of example, the electrically insulating layer 402 may comprise one or more layers of silicon dioxide (SiO₂), silicon nitride (Si₃N₄), engineered silicon carbide (having a resistivity of at least 10⁶ Ω-m), benzocylcobutene (BCB), polyimide, or non-piezoelectric (‘glassy’) aluminum nitride (AlN), which also provides comparatively good heat dissipation. Specifically, and as described more fully below, the electrically insulating layer 402 may comprise a plurality of layers, which may be comprised of the same or different materials.

A piezoelectric layer 405 comprises a lower surface 405″ in contact with a first electrode 404 and an upper surface 405′ in contact with a second electrode 406.

An optional passivation layer 407 is provided over the second electrode 106. Illustratively, the passivation layer 407 can be made from various types of materials, including aluminum nitride, silicon carbide, BSG, SiO₂, SiN, polysilicon, and the like.

A cantilevered portion 408 of the second electrode 406 is provided over a first sacrificial layer 431 on at least one side of the second electrode 406, and a bridge 409 is provided over a second sacrificial layer 432, and is disposed along the interconnection side 412. In accordance with a representative embodiment, illustrative candidates for the first and second sacrificial layers 431, 432 include, but are not limited, to amorphous or polycrystalline silicon, molybdenum (Mo), tungsten (W), germanium (Ge), SiGe, and titanium tungsten (TiW)

As depicted in FIG. 4, the second electrode 406 comprises an upper surface 406′. As can be seen, the upper surface 406′ is disposed substantially at a first height (z-dimension in the coordinate system depicted). Similarly, a cantilevered portion 408 comprises an upper surface 408′. The upper surface 408′ is disposed substantially at a second height (again, z-dimension in the coordinate system depicted). The second height is higher than the first height. Thus, the upper surface 406′ of the cantilevered portion 408 is raised up relative to the upper surface 206′.

As also depicted in FIG. 4, the bridge 409 has upper surface 409′. The upper surface 409′ is disposed substantially at a third height (again, z-dimension in the coordinate system depicted). The third height is higher than the first height. Thus, the upper surface 409′ is raised up relative to the upper surface 406′.

As noted above, using the XeF₂ release etch as described above is not a viable option when the first and second electrodes 404, 406, the cantilevered portion 408 and the bridge 409 are made of molybdenum, tungsten, or combinations thereof. Specifically, the etchant gas, XeF₂, will deteriorate the molybdenum/tungsten components. However, it is often desirable to use these materials for various metal components of BAW resonators. In an effort to prevent the interaction of the XeF₂ gas with the molybdenum/tungsten components, a protective layer 434 is disposed on a lower surface of the second electrode 406, and a photoresist mask (not shown) may be disposed over the second electrode 406. The photoresist mask has release openings (not shown) to allow the XeF₂ to reach first sacrificial layer 431 and the second sacrificial layer 432. Of course, the sacrificial island 421 is released in the reaction chamber at the same time. In accordance with a representative embodiment, the protective layer 434 is patterned milled by a known technique so it is not present over the upper surface 405′ of piezoelectric layer 405.

In accordance with a representative embodiment, the protective layer 434 is illustratively silicon carbide (SiC) or non-piezoelectric aluminum nitride, which substantially prevents the etchant XeF₂ from interacting with the second electrode 406, which may be molybdenum, tungsten, or a combination (e.g., alloy or stack) of these materials.

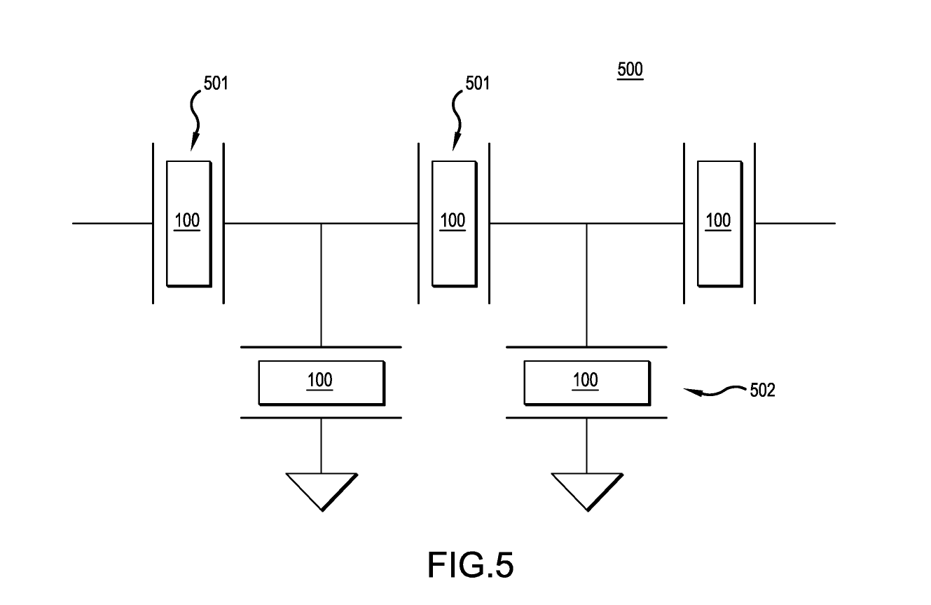

The BAW resonators 100-400 of the present teachings are contemplated for a variety of applications including wireless communication devices, and components thereof. By way of example, and as described in connection with FIG. 5, a plurality of BAW resonators 100 can be connected in a series/shunt arrangement to provide a ladder filter.

FIG. 5 shows a simplified schematic block diagram of an electrical filter 500 in accordance with a representative embodiment. The electrical filter 500 comprises series BAW resonators 501 and shunt BAW resonators 502. The series BAW resonators 501 and shunt BAW resonators 502 may each comprise BAW resonators 100 (or BAW resonators 200, 200′, or 300, or 400) described in connection with the representative embodiments of FIGS. 1-4. As can be appreciated, the BAW resonator devices (e.g., a plurality of BAW resonators 100) that comprise the electrical filter 500 may be provided over a common substrate, or may be a number of individual BAW resonator devices (e.g., BAW resonators 100) disposed over more than one substrate (e.g., more than one substrate). The electrical filter 500 is commonly referred to as a ladder filter, and may be used for example in duplexer applications. It is emphasized that the topology of the electrical filter 500 is merely illustrative and other topologies are contemplated. Moreover, the acoustic resonators of the representative embodiments are contemplated in a variety of applications including, but not limited to duplexers. As described above, the material selected for the electrically insulating layers 102, 302, 402 or the electrically insulating substrate 202, has a comparatively high resistivity. Beneficially, providing these layers/substrate having a such comparatively high resistivity may improve the quality factor (Q) in shunt BAW resonators (e.g., shunt BAW resonators 502) by reducing the shunt current due to their increased shunt resistance.

In accordance with illustrative embodiments, BAW resonators for various applications, such as in electrical filters and other components of wireless communication devices, are described. One of ordinary skill in the art appreciates that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

We claim:

1. A bulk acoustic wave (BAW) resonator, comprising:
an electrically insulating substrate;
a first electrode disposed on and in direct contact with an upper surface of the electrically insulating substrate;
a second electrode; and
a piezoelectric layer disposed between the first and second electrodes.

2. The BAW resonator of claim 1, wherein the electrically insulating substrate has an electrical resistivity between approximately 1×10⁶ Ω-m and approximately 5×10¹⁶ Ω-m.

3. The BAW resonator of claim 1, wherein the electrically insulating substrate comprises one of silicon dioxide (SiO₂), silicon nitride (Si₃N₄), benzocylcobutene (BCB), polyimide, and non-piezoelectric aluminum nitride (AlN).

4. The BAW resonator of claim 1, wherein an acoustic reflector exists in the electrically insulating substrate and beneath the first electrode.

5. The BAW resonator of claim 4, wherein the acoustic reflector comprises a cavity extending from an upper surface of the electrically insulating substrate.

6. The BAW resonator of claim 4, wherein the acoustic reflector comprises an acoustic Bragg reflector disposed in the electrically insulating layer.

7. The BAW resonator of claim 1, further comprising another layer disposed beneath the electrically insulating substrate.

8. The BAW resonator of claim 7, wherein the other layer comprises a semiconductor material.

9. The BAW resonator of claim 1, wherein the piezoelectric layer comprises aluminum nitride (AlN), doped with scandium (Sc), and a minimum atomic percentage of Sc is greater than approximately 5.0% and a maximum atomic percentage of Sc is approximately 44.0%.

10. The BAW resonator of claim 1, wherein the first electrode does not comprise either tungsten (W) or molybdenum (Mo).

11. The BAW resonator of claim 1, wherein the piezoelectric layer extends over an edge of the first electrode, and is in direct contact with an upper surface of the electrically insulating substrate.

12. The BAW resonator of claim 1, further comprising:
a first polymer post;
a second polymer post; and
a polymer lid disposed over the first and second polymer posts, wherein a void exists between an inner surface of the polymer lid, and an opposing inner surface of the electrically insulating layer.

13. An electrical filter comprising a plurality of the BAW resonators of claim 1.

14. A bulk acoustic wave (BAW) resonator, comprising:
an electrically insulating substrate;
a first electrode disposed over the electrically insulating substrate;
a second electrode comprising a plurality of sides;
a piezoelectric layer disposed between the first and second electrodes;
a bridge disposed adjacent to one of the plurality of sides of the second electrode; and
a protective layer disposed on a lower surface of the bridge, and between the lower surface of the bridge and a gap defined by the bridge.

15. The BAW resonator of claim 14, further comprising a cantilevered portion disposed on at least one of the plurality of sides of the second electrode, but not on the side of the second electrode comprising the bridge, wherein the protective layer is disposed on a lower surface of the cantilevered portion, and between the lower surface of the cantilevered portion and a gap defined by the cantilevered portion.

16. The BAW resonator as claimed in claim 15, wherein the first electrode, the second electrode, the bridge, and the cantilevered portion each comprise molybdenum (Mo), or tungsten (W), or a combination of Mo and W, and the protective layer prevents Xenon Difluoride (XeF₂) from substantially deteriorating any of the first electrode, the second electrode, the bridge, and the cantilevered portion.

17. The BAW resonator as claimed in claim 16, wherein the protective layer comprises aluminum nitride.

18. The BAW resonator of claim 14, wherein the electrically insulating substrate has an electrical resistivity between approximately 1×10⁶ Ω-m and approximately 5×10¹⁶ Ω-m.

19. The BAW resonator of claim 14, wherein the electrically insulating substrate comprises one of silicon dioxide (SiO₂), silicon nitride (Si₃N₄), benzocylcobutene (BCB), polyimide, and non-piezoelectric aluminum nitride (AlN).

20. The BAW resonator of claim 14, further comprising:
a first polymer post;
a second polymer post; and
a polymer lid disposed over the first and second polymer posts, wherein a void exists between an inner surface of the polymer lid, and an opposing inner surface of the electrically insulating layer.

21. A wireless communication device, comprising:
a semiconductor substrate;
an acoustic stack comprising a first electrode, a second electrode, and a piezoelectric layer disposed between the first and second electrode; and
an electrically insulating layer disposed between the acoustic stack and the semiconductor substrate, wherein the electrically insulating layer substantially electrically isolates the acoustic stack from electromagnetic radiation generated in the semiconductor substrate.

22. The wireless communication device of claim 21, wherein the semiconductor substrate comprises an upper surface with an outer perimeter, and wherein the electrically insulating layer is disposed on the upper surface of the semiconductor substrate covering entirely the outer perimeter.

23. The wireless communication device of claim 22, wherein the semiconductor substrate comprises a substrate outer perimeter and the electrically insulating layer has a layer outer perimeter, and wherein the substrate outer perimeter and the layer outer perimeter are aligned.

24. The wireless communication device of claim 21, further comprising an acoustic reflector disposed in the electrically insulating layer, and between the acoustic stack and the electrically insulating layer.

25. The wireless communication device of claim 24, wherein the electrically insulating layer comprises a first insulating layer comprising a first material and a second insulating layer comprising a second material.

26. The wireless communication device of claim 25, wherein the first material is different from the second material.

27. The wireless communication device of claim 21, wherein the electrically insulating layer has an electrical resistivity between approximately 1×10⁶ Ω-m and approximately 5×10¹⁶ Ω-m.

28. The wireless communication device of claim 21, wherein the electrically insulating layer comprises one of silicon dioxide (SiO₂), silicon nitride (Si₃N₄), benzocylcobutene (BCB), polyimide, and non-piezoelectric aluminum nitride (AlN).

29. The wireless communication device of claim 21, further comprising:
a first polymer post;
a second polymer post; and
a polymer lid disposed over the first and second polymer posts, wherein a void exists between an inner surface of the polymer lid, and an opposing inner surface of the electrically insulating layer.

30. The wireless communication device of claim 21, wherein the first electrode is in direct contact with an upper surface of the electrically insulating layer.

31. The wireless communication device of claim 21, wherein the piezoelectric layer extends over an edge of the first electrode, and is in direct contact with an upper surface of the electrically insulating layer.
